(19) United States
(12) Patent Application Publication
(10) Pub. No.: US 2021/0313540 A1
(43) Pub. Date: Oct. 7, 2021

(54) DISPLAY PANEL AND DISPLAY DEVICE

(71) Applicant: SHENZHEN ROYOLE TECHNOLOGIES CO., LTD., Shenzhen, Guangdong (CN)

(72) Inventors: Guanghong BI, Shenzhen, Guangdong (CN); Kun ZHANG, Shenzhen, Guangdong (CN); Wen-Chieh SHIH, Shenzhen, Guangdong (CN)

(21) Appl. No.: 17/259,952

(22) PCT Filed: Jul. 13, 2018
(86) PCT No.: PCT/CN2018/095618

§ 371 Date: Jan. 13, 2021

(51) Int. Cl. H01L 51/52; H01L 27/32

(52) U.S. Cl. CPC H01L 51/5228; H01L 51/5284; H01L 27/3218

(57) ABSTRACT

A display panel and a display device are provided. The display panel has a display region and a non-display region and includes an organic electroluminescence display layer. The organic electroluminescence display layer includes a first electrode, a light-emitting layer, and a second electrode. The light-emitting layer is disposed on a side of the first electrode. The second electrode is located in the display region and disposed on a side of the light-emitting layer away from the first electrode. An area of the second electrode is smaller than that of a layer connected with the second electrode, to allow at least part of external lights to reach the layer connected with the second electrode without being reflected by the second electrode.

### TECHNICAL FIELD

This disclosure relates to the field of display technologies, and particularly to a display panel and a display device.

### BACKGROUND

Organic electroluminescence displays have very good application prospects in various fields, such as media, games, multimedia teaching, aircraft, and engineering vehicle operation control. The organic electroluminescent display has a reflectivity, especially in a strong light environment (e.g., an outdoor sunlight environment), there will be strong reflected lights on a surface of a front screen of the display, which causes white display, blurred display, and decreased display contrast. As a result, normal reading and recognition of display contents are seriously affected. The organic electroluminescence display includes a reflective layer or a device structure that can reflect ambient lights, such as a cathode layer. In a traditional method of preparing the organic electroluminescence layer, a reflectivity of electrode materials is relatively high due to overall coating of a cathode, which greatly reduces display contrast of the organic electroluminescent display under external lights.

### SUMMARY

In view of the above deficiencies, implementations of the disclosure provide a display panel, which can reduce a reflectivity of an electrode layer of the display panel.

Technical solutions are as follows.

In implementations of the disclosure, a display panel is provided. The display panel has a display region and a non-display region and includes an organic electroluminescence display layer. The organic electroluminescence display layer includes a first electrode, a light-emitting layer, and a second electrode. The light-emitting layer is disposed on a side of the first electrode. The second electrode is located in the display region and disposed on a side of the light-emitting layer away from the first electrode. An area of the second electrode is smaller than that of a layer connected with the second electrode, to allow at least part of external lights to reach the layer connected with the second electrode without being reflected by the second electrode.

In one implementation, the first electrode is an anode and the second electrode is a cathode.

In one implementation, a reflectivity of the first electrode is lower than that of the second electrode.

In one implementation, the layer connected with the second electrode is the light-emitting layer.

In one implementation, the second electrode includes a plurality of sub-second electrodes, and the sub-second electrodes are separated by gaps, where the gaps allow part of the external lights to pass through.

In one implementation, the display region includes a plurality of pixel regions and pixel-gap regions among the pixel regions, and the pixel-gap regions overlap with at least part of the gaps.

In one implementation, the pixel region includes a plurality of sub-pixel regions and sub-pixel gap regions among the sub-pixel regions, and the sub-pixel gap regions overlap with at least part of the gaps.

In one implementation, an area of a single sub-second electrode is smaller than that of a sub-pixel region corresponding to the single sub-second electrode.

In one implementation, the sub-second electrode is in a shape of at least of a triangle, a square, a diamond, a circle, a polygon, and an irregular pattern.

In one implementation, the display panel further includes a substrate. The substrate is located on one side of the organic electroluminescence display layer and provided with a light-absorbing coating, where the light-absorbing coating is configured to absorb external lights passing through the gaps.

In one implementation, the light-absorbing coating is disposed on a surface of the substrate adjacent to the second electrode.

In one implementation, the substrate is located on one side of the first electrode away from the light-emitting layer, the second electrode is semi-transmissive and semi-reflective, and the first electrode is opaque.

In one implementation, the substrate is located on one side of the second electrode away from the light-emitting layer, the second electrode is opaque, and the first electrode is transparent.

In one implementation, the substrate has a radiation region, where the radiation region is a region where lights emitted by the light-emitting layer and the external lights reach the substrate through the gaps, and the light-absorbing coating at least covers the radiation region.

In one implementation, a first sub-second electrode is disposed on one side of the gap and a second sub-second electrode is disposed on the other side of the gap. The first sub-second electrode includes a first surface, a second surface opposite to the first surface, and a first side surface, where the first surface is disposed closer to the substrate than the second surface, the first side surface intersects with the first surface at a first intersection point, and the first side surface intersects with the second surface at a second intersection point. The second sub-second electrode includes a third surface, a fourth surface opposite to the third surface, and a second side surface, where the third surface is disposed closer to the substrate than the fourth surface, the second side surface intersects with the third surface at a third intersection point, and the second side surface intersects with the fourth surface at a fourth intersection point. The first side surface and the second side surface define the gap there between. The light-absorbing coating includes a first boundary point and a second boundary point. The second intersection point, the third intersection point, and the second boundary point are collinear, and the fourth intersection point, the first intersection point, and the first boundary point are collinear.

In one implementation, the display panel further includes an absorption layer. After external lights pass through the absorption layer, an intensity of the external lights is weakened, and then the external lights reach the second electrode.

In one implementation, the absorption layer is located on one side of the light-emitting layer. The absorption layer includes a fifth surface and a sixth surface opposite to the fifth surface, where the sixth surface is disposed closer to the light-emitting layer than the fifth surface. The absorption layer is configured to absorb external lights incident on the fifth surface and external lights incident on the sixth surface after being reflected, to make a ratio of an intensity of external lights emitted from the fifth surface to an intensity of external lights incident on the fifth surface less than a preset value.

In implementations of the disclosure, a display device is provided. The display device includes the above display panel.

Advantageous effects: according to the display panel of the implementations of the disclosure, the area of the second electrode is made to be smaller than the area of the layer connected with the second electrode. In this way, a reflectivity of the second electrode to external lights can be reduced, thereby improving display contrast of the display panel.

### BRIEF DESCRIPTION OF THE DRAWINGS

In order to describe technical solutions of implementations more clearly, the following will give a brief description of accompanying drawings used for describing the implementations. Apparently, accompanying drawings described below are merely some implementations. Those of ordinary skill in the art can also obtain other accompanying drawings based on the accompanying drawings described below without creative efforts.

FIG. 1 is a schematic structural diagram illustrating a display panel according to a first implementation of the disclosure.

FIG. 2 is a top view of FIG. 1.

FIG. 3 to FIG. 7 are schematic diagrams illustrating distribution of sub-second electrodes in the display panel according to implementations of the disclosure.

FIG. 8 is a schematic structural diagram illustrating a display panel according to a second implementation of the disclosure.

FIG. 9 is a schematic structural diagram illustrating a display panel according to a third implementation of the disclosure.

FIG. 10 is a schematic structural diagram illustrating a display panel according to a fourth implementation of the disclosure.

FIG. 11 is a schematic structural diagram illustrating a display panel according to a fifth implementation of the disclosure.

FIG. 12 is a schematic structural diagram illustrating a display panel according to a sixth implementation of the disclosure.

FIG. 13 is a schematic structural diagram illustrating a display device according to an implementation of the disclosure.

### DETAILED DESCRIPTION

Hereinafter, technical solutions embodied by implementations of the disclosure will be described in a clear and comprehensive manner with reference to the accompanying drawings intended for the implementations. It is evident that the implementations described herein constitute merely some rather than all the implementations of the disclosure, and that those of ordinary skill in the art will be able to derive other implementations based on these implementations without making creative efforts, which all such derived implementations shall all fall in the protection scope of the disclosure.

The terms “first”, “second”, and the like used in the specification, the claims, and the accompany drawings of the disclosure are used to distinguish different objects rather than describe a particular order. The terms “include”, “comprise”, and “have” as well as variations thereof are intended to cover non-exclusive inclusion. For example, a process, method, system, product, or device including a series of steps or units is not limited to the listed steps or units, on the contrary, it can optionally include other steps or units that are not listed; alternatively, other steps or units inherent to the process, method, product, or device can be included either.

The term “implementation” referred to herein means that particular features, structures, or properties described in conjunction with the implementations may be defined in at least one implementation of the disclosure. The phrase “implementation” appearing in various places in the specification does not necessarily refer to the same implementation or an independent/ alternative implementation that is mutually exclusive with other implementations. Those skilled in the art will understand expressly and implicitly that an implementation described herein may be combined with other implementations.

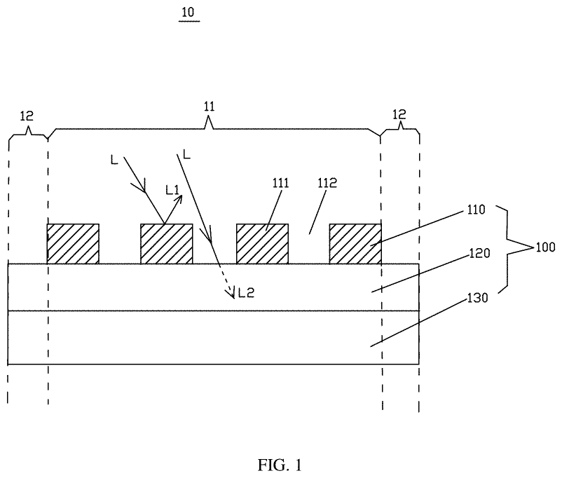

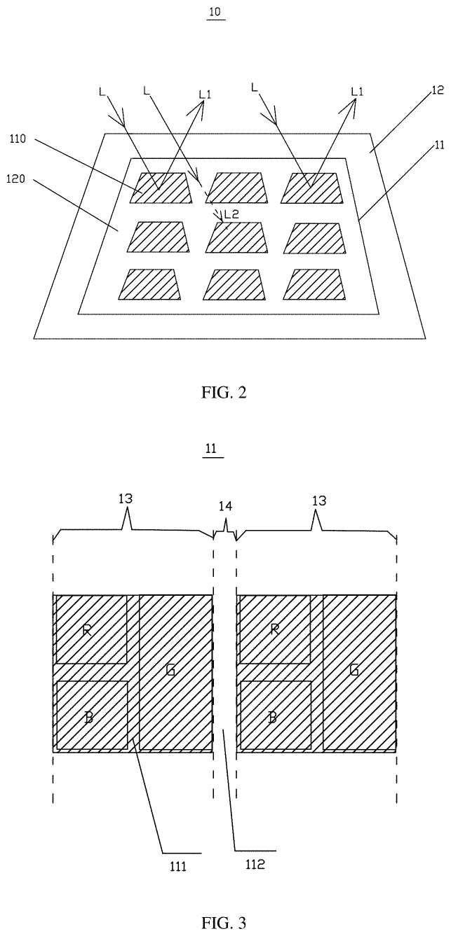

According to a first implementation of the disclosure, a display panel 10 is provided. As illustrated in FIG. 1 and FIG. 2, the display panel 10 includes an organic electroluminescence display layer 100. The display panel 10 has a display region 11 and a non-display region 12. The organic electroluminescence display layer 100 includes a second electrode 110, a light-emitting layer 120, and a first electrode 130. The light-emitting layer 120 is disposed on a side of the first electrode 130. The second electrode 110 is disposed on a side of the light-emitting layer 120 away from the first electrode 130 and is located in the display region 11. The second electrode 110 is configured to reflect external lights incident into the display panel 10. An area of the second electrode 110 is smaller than an area of a layer connected with the second electrode 110, to allow at least part of the external lights to reach the layer connected with the second electrode 110 without being reflected by the second electrode 110. The second electrode 110 may be patterned to make the area of the second electrode 110 smaller than the area of the layer connected with the second electrode 110. In an implementation, the layer connected with the second electrode 110 is the light-emitting layer 120. Part of the external lights (L1) are reflected after incident on the surface of the second electrode 110, and part of the external lights (L2) reach the light-emitting layer 120 after incident on the display region 11 except the second electrode 110. In this way, a reflectivity of the second electrode 110 to the external lights can be reduced. The external lights incident on the display region 11 for example is L, and lights reflected by the second electrode 110 for example is L1, a ratio of the intensity of L1 to the intensity of L is the reflectivity of the second electrode 110. The more the lights L2 incident on the light-emitting layer 120, the lower the reflectivity of the second electrode 110.

In an implementation, the first electrode 130 is an anode, and the second electrode 110 is a cathode. That is, an area of the cathode is smaller than an area of a layer connected with the cathode. For example, the cathode is patterned to make the area of the cathode smaller than an area of the light-emitting layer 120.

In an implementation, a reflectivity of the first electrode 130 is lower than the reflectivity of the second electrode 110. In this implementation, since the reflectivity of the first electrode 130 is lower than the reflectivity of the second electrode 110, a reflectivity of the organic electroluminescence display layer 100 to the external lights mainly depends on the reflectivity of the second electrode 110. According to the technical solutions of the disclosure, the area of the second electrode 110 is smaller than the area of the layer connected with the second electrode 110, so that more external lights reach the connected layer without being reflected by the second electrode 110, which can reduce the reflectivity of the second electrode 110, thereby reducing the reflectivity of the organic electroluminescence display layer 100 to the external lights and improving display contrast of the display panel 10.

In an implementation, as illustrated in FIG. 1, the second electrode 110 includes multiple sub-second electrodes 111. The sub-second electrodes 111 are separated by gaps 112, where the gaps 112 allow part of the external lights L2 to pass through. Part of the external lights L2 pass through the gaps 112 without being reflected by the sub-second electrodes 111, so that the reflectivity of the second electrode 110 to the external lights L is reduced. The sub-second electrodes 111 can be realized by patterning the second electrode 110, and the sub-second electrodes 111 may be distributed in a matrix on a surface of the light-emitting layer 120. Part of the external lights L2 passing through the gaps 112 can be absorbed by other film layers lower than the second electrode 110.

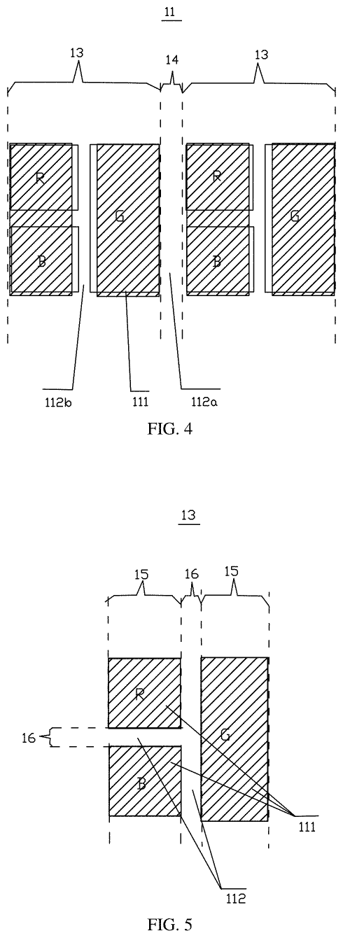

In an implementation, as illustrated in FIG. 3 and FIG. 4, the display region 11 includes multiple pixel regions 13 and multiple pixel-gap regions 14 distributed among the pixel regions 13. The pixel-gap regions 14 overlap with at least part of the gaps 112. The pixel region 13 refers to a region occupied by a pixel. When the pixel-gap regions 14 overlap with the gaps 112, the size of the sub-second electrode 111 is equal to that of the pixel region 13, that is, the distribution of the gaps 112 is the same as that of the pixel-gap regions 14 (see FIG. 3, which merely illustrates part of the display region 11 for explanation). When an area of the sub-second electrode 111 is smaller than an area of the pixel region 13, the pixel-gap regions 14 overlap with part of the gaps 112 (see FIG. 4). For example, in FIG. 4, the pixel-gap region 14 overlaps with a gap 112a, but does not overlap with a gap 112b. The “a” in the reference number “112a” and the “b” in the reference number “112b” are used to distinguish the gaps 112 at different positions. In this implementation, an area of the gaps 112 in the second electrode 110 can be increased, which ensures an aperture ratio of the second electrode 110, thereby reducing a reflectivity of the display region 11 and increasing light transmittance of the display region 11 as much as possible. The patterned sub-second electrode 11 is disposed in the pixel region, and the area of the sub-second electrode 11 is made to be equal to or smaller than the area of the pixel region 13, which can reduce the reflectivity of the second electrode 110 to the external lights while ensuring a power supply function of the second electrode 110 to the light-emitting layer 120.

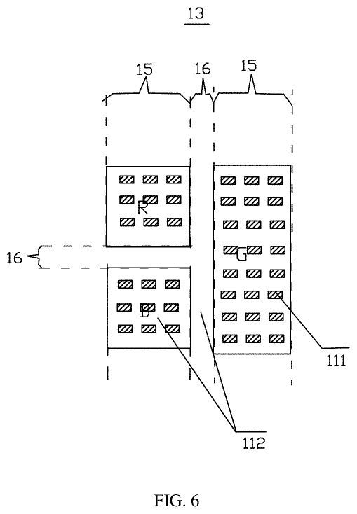

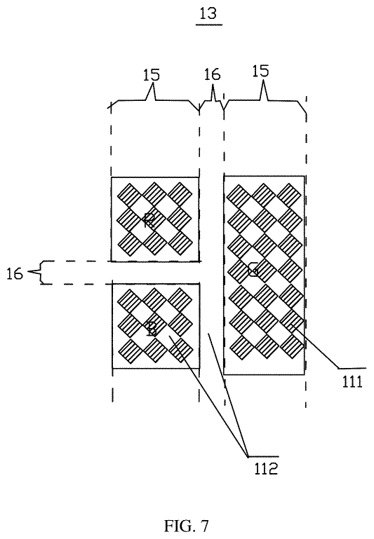

In an implementation, as illustrated in FIG. 5 and FIG. 6, the pixel region 13 includes sub-pixel regions 15 and sub-pixel gap regions 16 among the sub-pixel regions 15. The sub-pixel gap regions 16 overlap with at least part of the gaps 112. The sub-pixel region 15 refers to a region occupied by a sub-pixel. When the sub-pixel gap regions 16 overlap with the gaps 112, the size of the sub-second electrode 111 is equal to the sub-pixel region 15, that is, the distribution of the gaps 112 is the same as that of the sub-pixel gap regions 16 (see FIG. 5). When a red sub-pixel, a green sub-pixel, and a blue sub-pixel each have different areas (i.e., sizes), the second sub-electrodes 111 can be patterned according to the sizes of the three sub-pixels, so that the distribution of the gaps 112 is the same as that of the sub-pixel gap regions 16. When the area of the sub-second electrode 111 is smaller than the area of the sub-pixel region 15, the sub-pixel gap regions 16 overlap with part of the gaps 112 (see FIG. 6 and FIG. 7). The sub-second electrodes 111 may be distributed in a matrix in the sub-pixel region 15. In this implementation, the area of the gaps 112 in the second electrode 110 and the aperture ratio of the second electrode 110 can be further increased, thereby reducing the reflectivity of the second electrode 110 or increasing a light transmittance of the external lights passing through the gaps.

In an implementation, an area of a single sub-second electrode 110 is smaller than an area of a sub-pixel region 15 corresponding to the single sub-second electrode 110. A sub-pixel region 15 is provided with at least one sub-second electrode 111 (see FIG. 6 and FIG. 7). The area of the sub-second electrode 111 can be set according to a luminous efficiency of each sub-pixel. For a sub-pixel with a relatively low luminous efficiency, the area of the sub-second electrode 111 is increased to improve an electrode excitation effect. As such, the luminous efficiency can be increased, and a lifetime of the sub-pixel can be prolonged. For pixels with different luminous efficiencies, areas of the sub-second electrodes 111 can also be set, to achieve uniform display of the display region 11.

In an implementation, the sub-second electrode 111 is in a shape of at least of a triangle, a square, a diamond, a circle, a polygon, and an irregular pattern. The shape of the sub-second electrode 111 in the FIG. 3 to FIG. 7 may be any of the shapes.

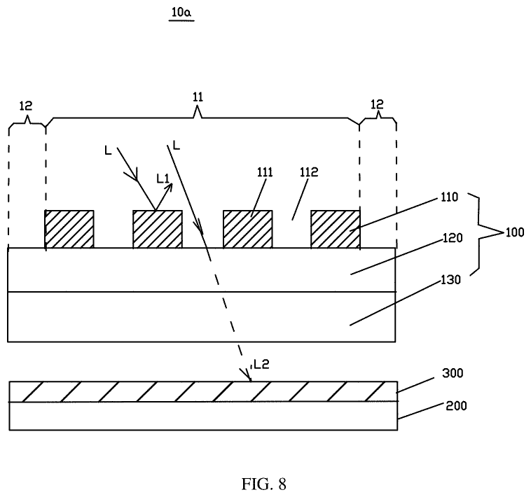

According to a second implementation of the disclosure, a display panel 10a is provided. As illustrated in FIG. 8, the display panel 10a further includes a substrate 200. The substrate 200 is located on one side of the organic electroluminescence display layer 100. The substrate 200 is provided with a light-absorbing coating 300, where the light-absorbing coating 300 is configured to absorb external lights passing through the gaps 112. When part of the external lights L2 pass through the gaps 112 to reach the substrate 200, since the substrate 200 may reflect the part of the external lights L2 passing through the gaps 112, the reflectivity of the display region 11 to the external lights L is increased. To this end, in this implementation, the light-absorbing coating 300 is disposed on the substrate 200, which can absorb external lights passing through the gaps 112. When part of lights emitted by the light-emitting layer 120 are absorbed by the light-absorbing coating 300, power of the light-emitting layer 120 can be increased appropriately, to avoid the display brightness of the light-emitting layer 120 being reduced because the lights are absorbed. The substrate 200 is opaque.

In an implementation, the light-absorbing coating 300 is disposed on a surface of the substrate 200 close to the second electrode 110. The light-absorbing coating 300 is disposed adjacent to the second electrode 110 to better absorb the natural lights passing through the gaps 112. Compared with disposing the light-absorbing coating 300 on a surface of the substrate 200 away from the second electrode 110, a total reflectivity can be further reduced in this case.

In an implementation, the substrate 200 is located on one side of the first electrode 130 away from the light-emitting layer 120, the second electrode 110 is semi-transmissive and semi-reflective, and the first electrode 130 is opaque. That is, lights emitted by the light-emitting layer 120 are emitted from a side of the second electrode 110 away from the light-emitting layer 120, and the display panel 10a as a whole is top-emitting. The expression that “the first electrode 130 is opaque” means that a light transmittance of the first electrode 130 is smaller than a preset light transmittance of the second electrode 110, so that the lights emitted by the light-emitting layer 120 are emitted from the second electrode 110.

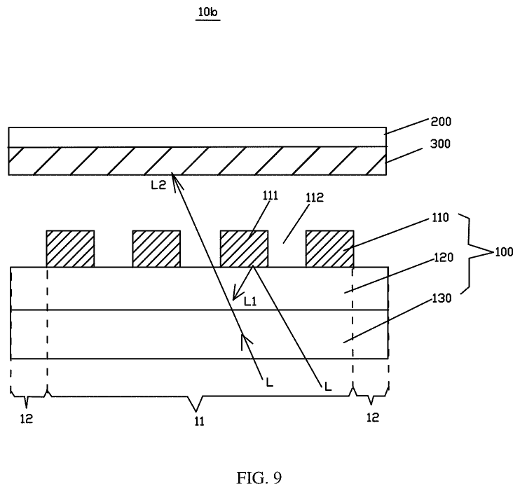

According to a third implementation of the disclosure, a display panel 10b is provided. As illustrated in FIG. 9, the substrate 200 is located on one side of the second electrode 110 away from the light-emitting layer 120. The second electrode 110 is opaque and the first electrode 130 is transparent. That is, lights emitted by the light-emitting layer 120 are emitted from a side of the first electrode 130 away from the light-emitting layer 120, and the display panel 10b as a whole is bottom-emitting. As an example, the light transmittance of the first electrode 130 is greater than 80%. The first electrode 130 is made of a transparent electrode material.

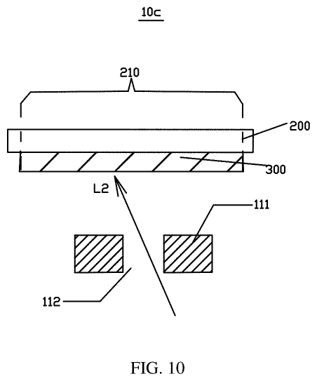

According to a fourth implementation of the disclosure, a display panel 10c is provided. As illustrated in FIG. 10, the substrate 200 includes a radiation region 210. The radiation region 210 refers to a region where lights emitted by the light-emitting layer 120 and the external lights reach the substrate 200 through the gaps 112. The light-absorbing coating 300 at least covers the radiation region 210. The light-absorbing coating 300 at least covering the radiation region 210 can ensure that the light-absorbing coating 300 absorbs external lights incident on the substrate 200 through the gaps 112.

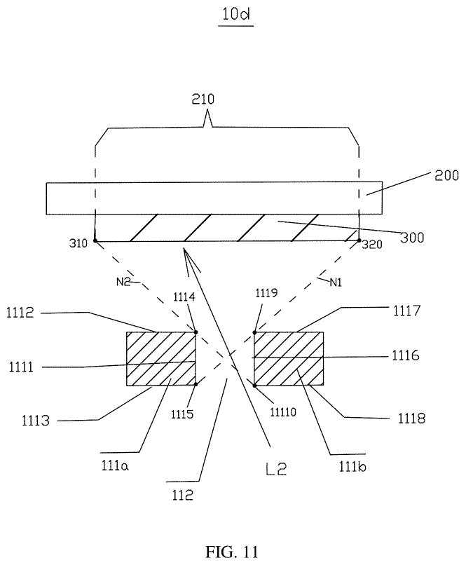

According to a fifth implementation of the disclosure, a display panel 10d is provided. As illustrated in FIG. 11, a first sub-second electrode 111a is disposed on one side of the gap 112 of the display panel 10d, and a second sub-second electrode 111b is disposed on the other side of the gap 112 of the display panel 10d. The term “first” in the “first sub-second electrode 111a” and the term “second” in the “second sub-second electrode 111b” are used to distinguish the sub-second electrodes 111 at different positions. FIG. 11 is schematic structural diagram illustrating the sub-second electrodes 111 and the light-absorbing coating 300 in part of the display panel 10d, which is also applicable to a structure of the sub-second electrodes 111 and the light-absorbing coating 300 in other parts of the display panel 10d.

The first sub-second electrode 111a includes a first side surface 1111, a first surface 1112, and a second surface 1113 opposite to the first surface 1112. The first surface 1112 is disposed closer to the substrate 200 than the second surface 1113. The first side surface 1111 intersects with the first surface 1112 at a first intersection point 1114, and the first side surface 1111 intersects with the second surface 1113 at a second intersection point 1115.

The second sub-second electrode 111b includes a second side surface 1116, a third surface 1117, and a fourth surface 1118 opposite to the third surface 1117. The third surface 1117 is disposed closer to the substrate 200 than the fourth surface 1118. The second side surface 1116 intersects with the third surface 1117 at a third intersection point 1119, and the second side surface 1116 intersects with the fourth surface 1118 at a fourth intersection point 11110.

The first side surface 1111 and the second side surface 1116 define the gap 112 there between. The light-absorbing coating 300 includes a first boundary point 310 and a second boundary point 320. The first boundary point 310 is opposite to the second boundary point 320.

The second intersection point 1115, the third intersection point 1119, and the second boundary point 320 are located on a same straight line N1 (i.e., collinear), and the fourth intersection point 11110, the first intersection point 1114, and the first boundary point 310 are located on a same straight line N2. When lights L2 incident from the second intersection point 1115 along a direction N1 and reach the second boundary point 320, the lights can be absorbed by the light-absorbing coating 300. Similarly, when the lights L2 incident from the fourth intersection point 11110 along a direction N2 and reach the first boundary point 310, the lights can be absorbed by the light-absorbing coating 300. Accordingly, lights L2 incident from any position between the second intersection point 1115 and the fourth intersection point 11110 can reach the light-absorbing coating 300 between the first boundary point 310 and the second boundary point 320, and be absorbed by the light-absorbing coating 300.

With aid of the structure of the light-absorbing coating 300 and the sub-second electrodes 111 of the fifth implementation, the light-absorbing coating 300 with a suitable coating area can effectively absorb external lights incident on the substrate 200, which can save the material of the light-absorbing coating 300.

According to a sixth implementation of the disclosure, a display panel 10e is provided. As illustrated in FIG. 12, the display panel 10e further includes an absorption layer 400. An intensity of the external lights is weakened after passing through the absorption layer 400, and then the external lights incident on the second electrode 110. The absorption layer 400 can reduce the intensity of lights reaching the second electrode 110, and accordingly, the intensity of lights reflected by the second electrode 110 is weakened, which further reduces the reflectivity of the display panel 10e to the external lights, thereby improving display contrast.

In an implementation, the absorption layer 400 is located on one side of the light-emitting layer 120. The absorption layer 400 includes a fifth surface 410 and a sixth surface 420 opposite to the fifth surface 410. The sixth surface 420 is disposed closer to the light-emitting layer 120 than the fifth surface 410. The absorption layer 400 is configured to absorb external lights L incident on the fifth surface 410 and external lights incident on the sixth surface 420 after being reflected, to make a ratio of the intensity of external lights emitted from the fifth surface 410 to the intensity of external lights incident on the fifth surface 410 less than a preset value.

As illustrated in FIG. 12, after the external lights L are incident on the fifth surface 410 of the absorption layer 400, part of the external lights L (L3) are not absorbed by the absorption layer 400 and are incident on the organic electroluminescence display layer 100. Part of L3 (L6) are absorbed by the organic electroluminescence display layer 100, part of L3 (L4) are reflected by the organic electroluminescence display layer 100 and incident into the absorption layer 400 again from the sixth surface 420. Part of L4 are absorbed by the absorption layer 400, and remaining unabsorbed part of L4 (L5) are emitted outside from the fifth surface 410. A ratio of the intensity of L5 to the intensity of L is set to be less than the preset value, so that a total reflectivity of the flexible display panel 10e to the external lights can be reduced. The preset value may be 6%. For example, the absorption layer 400 has an absorption rate of 50% and the organic electroluminescence display layer 100 has a reflectivity of 24%, the intensity of L5 is 15, the intensity of L is I, and accordingly, the intensity of L5 is calculated as 15=I*(1−50%)*24%*(1−50%)=6%I, which means that the ratio of the intensity of L5 to the intensity of L is 6%. When the absorption rate of the absorption layer 400 increases and the reflectivity of the organic electroluminescence display layer 100 decreases, the final ratio decreases. The absorption rate of the absorption layer 400 can be controlled by adjusting materials, thickness, color depth, etc. of the absorption layer 400. The reflectivity of the organic electroluminescence display layer 100 can be achieved by setting the area of the second electrode 110 to be smaller than the area of the light-emitting layer 120 in the foregoing implementations of the disclosure. The absorption layer 400 may be a black absorption layer or a dark absorption layer. The absorption layer 400 may be a black silicon material, a black dye, or the like. Absorbing the part of L3 (L6) by the organic electroluminescence display layer 100 can be achieved by providing the light-absorbing coating 300.

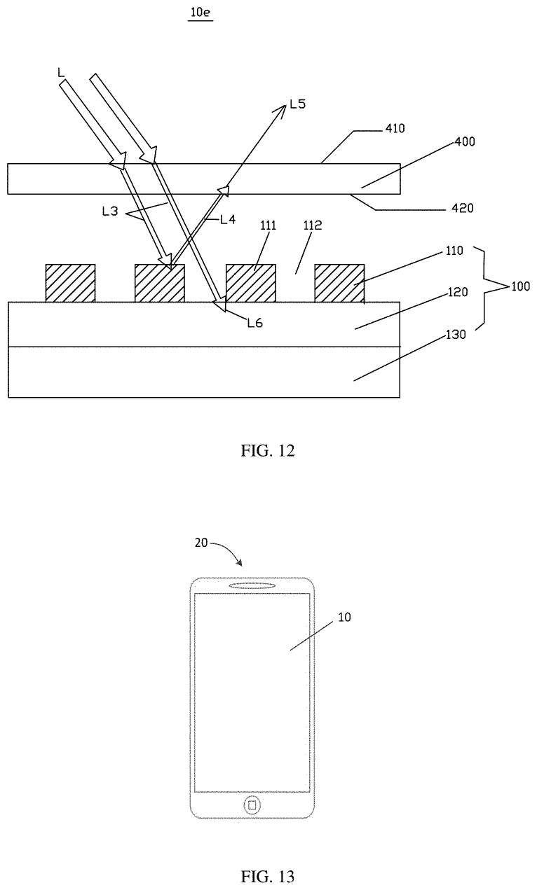

According to the disclosure, a display device 20 is further provided. As illustrated in FIG. 13, the display device 20 includes the display panel 10 described in any of the foregoing implementations. The display device 20 may be, but is not limited to, an e-book, a smart phone (e.g., an Android phone, an iOS phone, a Windows Phone phone, etc.), a tablet computer, a flexible palm computer, a flexible notebook computer, and a mobile Internet device (MID) or a wearable device, etc., or may be an organic light-emitting diode (OLED) display device, or an active matrix organic light emitting diode (AMOLED) display device.

The foregoing description merely depicts some illustrative implementations of the disclosure, which however are not intended to limit the disclosure. Any modifications, equivalent substitutions, or improvements made by those skilled in the art without departing from the spirits and principles of the disclosure shall all be encompassed within the protection scope of the disclosure. The protection scope of the disclosure should be defined by the appended claims and equivalents of the appended claims.

1. A display panel, having a display region and a non-display region, and comprising an organic electroluminescence display layer, the organic electroluminescence display layer comprising:
a first electrode;
a light-emitting layer, disposed on a side of the first electrode; and
a second electrode, located in the display region and disposed on a side of the light-emitting layer away from the first electrode; an area of the second electrode being smaller than that of a layer connected with the second electrode, to allow at least part of external lights to reach the layer connected with the second electrode without being reflected by the second electrode.

2. The display panel of claim 1, wherein the first electrode is an anode and the second electrode is a cathode.

3. The display panel of claim 1, wherein a reflectivity of the first electrode is lower than that of the second electrode.

4. The display panel of claim 1, wherein the layer connected with the second electrode is the light-emitting layer.

5. The display panel of claim 1, wherein the second electrode comprises a plurality of sub-second electrodes, and the sub-second electrodes are separated by gaps, wherein the gaps allow part of the external lights to pass through.

6. The display panel of claim 5, wherein the display region comprises a plurality of pixel regions and pixel-gap regions among the pixel regions, and the pixel-gap regions overlap with at least part of the gaps.

7. The display panel of claim 6, wherein the pixel region comprises a plurality of sub-pixel regions and sub-pixel gap regions among the sub-pixel regions, and the sub-pixel gap regions overlap with at least part of the gaps.

8. The display panel of claim 7, wherein an area of a single sub-second electrode is smaller than that of a sub-pixel region corresponding to the single sub-second electrode.

9. The display panel of claim 5, wherein the sub-second electrode is in a shape of at least of a triangle, a square, a diamond, a circle, a polygon, and an irregular pattern.

10. The display panel of claim 5, further comprising:
a substrate, located on one side of the organic electroluminescence display layer and provided with a light-absorbing coating, wherein the light-absorbing coating is configured to absorb external lights passing through the gaps.

11. The display panel of claim 10, wherein the light-absorbing coating is disposed on a surface of the substrate adjacent to the second electrode.

12. The display panel of claim 11, wherein the substrate is located on one side of the first electrode away from the light-emitting layer, the second electrode is semi-transmissive and semi-reflective, and the first electrode is opaque.

13. The display panel of claim 11, wherein the substrate is located on one side of the second electrode away from the light-emitting layer, the second electrode is opaque, and the first electrode is transparent.

14. The display panel of claim 13, wherein the substrate has a radiation region, wherein the radiation region is a region comprises a first region where lights emitted by the light-emitting layer reach the substrate through the gaps, and a second region where the external lights reflected below the substrate reach the substrate through the gaps, and the light-absorbing coating at least covers the radiation region.

15. The display panel of claim 10, comprising:
a first sub-second electrode disposed on one side of the gap and a second sub-second electrode disposed on the other side of the gap, wherein
the first sub-second electrode comprises a first surface, a second surface opposite to the first surface, and a first side surface, wherein the first surface is disposed closer to the substrate than the second surface, the first side surface intersects with the first surface at a first intersection point, and the first side surface intersects with the second surface at a second intersection point;
the second sub-second electrode comprises a third surface, a fourth surface opposite to the third surface, and a second side surface, wherein the third surface is disposed closer to the substrate than the fourth surface, the second side surface intersects with the third surface at a third intersection point, and the second side surface intersects with the fourth surface at a fourth intersection point;
the first side surface and the second side surface define the gap there between;
the light-absorbing coating comprises a first boundary point and a second boundary point; and
the second intersection point, the third intersection point, and the second boundary point are collinear, and the fourth intersection point, the first intersection point, and the first boundary point are collinear.

16. The display panel of claim 1, further comprising:
an absorption layer, after external lights pass through the absorption layer, an intensity of the external lights is weakened, and then the external lights reach the second electrode.

17. The display panel of claim 16, wherein
the absorption layer is located on one side of the light-emitting layer;
the absorption layer comprises a fifth surface and a sixth surface opposite to the fifth surface, wherein the sixth surface is disposed closer to the light-emitting layer than the fifth surface; and
the absorption layer is configured to absorb external lights incident on the fifth surface and external lights incident on the sixth surface after being reflected, to make a ratio of an intensity of external lights emitted from the fifth surface to an intensity of external lights incident on the fifth surface less than a preset value.

18. A display device, comprising:
a display panel, having a display region and a non-display region, and comprising an organic electroluminescence display layer, the organic electroluminescence display layer comprising:
a first electrode;
a light-emitting layer, disposed on a side of the first electrode; and
a second electrode, located in the display region and disposed on a side of the light-emitting layer away from the first electrode; an area of the second electrode being smaller than that of a layer connected with the second electrode, to allow at least part of external lights to reach the layer connected with the second electrode without being reflected by the second electrode.

19. The display device of claim 18, the second electrode comprises a plurality of sub-second electrodes, and the sub-second electrodes are separated by gaps, wherein the gaps allow part of the external lights to pass through.

20. The display device of claim 18, wherein the display panel further comprises:
an absorption layer, after external lights pass through the absorption layer, an intensity of the external lights is weakened, and then the external lights reach the second electrode.
